(19) United States
(12) Patent Application Publication
(10) Pub. No.: US 2003/0089458 A1
(43) Pub. Date: May 15, 2003

(54) Wafer processing member

(75) Inventor: Hirotaka Hagihara, Yamagata (JP)

Correspondence Address: FOLEY AND LARDNER, SUITE 500, 3000 K STREET NW, WASHINGTON, DC, 20007, US

(73) Assignee: TOSHIBA CERAMICS CO., LTD.

(21) Appl. No.: 10/205,199

(22) Filed: Jul. 26, 2002

(30) Foreign Application Priority Data
Jul. 30, 2001 (JP) 2001-230133
Jan. 22, 2002 (JP) 2002-013175

(51) Int. Cl. C23F 1/00; C23C 16/00

(52) U.S. Cl. 156/345.51; 118/723 R; 118/728; 156/345.1

(57) ABSTRACT

A wafer processing member having: a base material made of a material isotropic in all in-plane directions; and a ceramic film with which the base material is coated; wherein: the base material has a thickness of not larger than 3 mm; difference in coefficient of thermal expansion between the base material and the ceramic film is in a range of from 0.6×10⁻⁶ to 1.2×10⁻⁶/° C.; and variation in coefficient of thermal expansion of the base material in all in-plane directions is not larger than 0.05×10⁻⁶/° C.

### BACKGROUND OF THE INVENTION

The present invention relates to a semiconductor member used in a semiconductor heating operation and particularly to a wafer processing member used in an operation of giving heating treatment to a semiconductor wafer.

A semiconductor member formed from a base material coated with a ceramic film has been heretofore used mainly in a heating treatment step such as an epitaxial growth step or a plasma CVD step in a semiconductor producing process.

A combination of several blocks may be used as a member used when a wafer is heated. Such a combination type member requires both smooth combination of blocks and extremely small gaps between adjacent blocks.

In a conventional wafer processing member, shapes of respective portions in a product can be adjusted but no consideration is given to roundness and combination. Moreover, the physical property of the base material is selected carefully to thereby prevent the conventional wafer processing member from being deformed.

The coefficient of thermal expansion of the conventional base material varies in accordance with directions. Hence, the wafer processing member using the conventional base material may be deformed in use because the dimensions of the base material vary in accordance with directions in accordance with the variation in quantity of thermal expansion. This deformation problem is particularly remarkable in a wafer processing member such as a combination type member strictly requiring high dimensional accuracy.

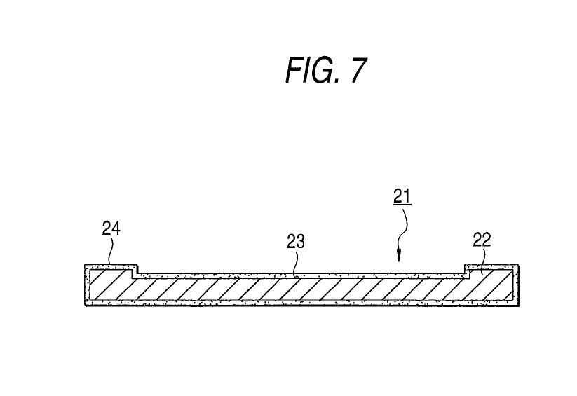

As shown in FIG. 7, the conventional wafer processing member is formed by providing a recess 23 in only one surface of a base material 22 and then coating the whole surface of the base material 22 with a ceramic film 24.

The thickness of the ceramic film after use is eroded by about 5 μm to about 20 μm compared with the thickness of the ceramic film before use. Such variation of the ceramic film with the passage of time also causes the deformation of the wafer processing member. Further, there is a problem that the wafer processing member is deformed because internal stress imposed on the outer circumferential portion cannot be made uniform.

Hence, there is a great demand for a wafer processing member which is prevented from being deformed due to thermal expansion even in the case where the wafer processing member is used in heating treatment or the like.

### SUMMARY OF THE INVENTION

The invention is designed in consideration of such situations and an object of the invention is to provide a wafer processing member which is prevented from being deformed due to thermal expansion even in the case where the wafer processing member is used in heating treatment.

In order to achieve the object, according to the first aspect of the invention, there is provided a wafer processing member having: a base material made of a material isotropic in all in-plane directions; and a ceramic film with which the base material is coated; wherein: the base material has a thickness of not larger than 3 mm; difference in coefficient of thermal expansion between the base material and the ceramic film is in a range of from 0.6×10⁻⁶ to 1.2×10⁻⁶/° C.; and variation in coefficient of thermal expansion of the base material in all in-plane directions is not larger than 0.05×10⁻⁶/° C.

According to the second aspect of the invention, there is provided a wafer processing member having: a base material made of a material isotropic in three-dimensional directions; and a ceramic film with which the base material is coated; wherein: difference in coefficient of thermal expansion between the base material and the ceramic film in three-dimensional directions of the base material is in a range of from 0.6×10⁻⁶ to 1.2×10⁻⁶/° C.; and variation in coefficient of thermal expansion of the base material in three-dimensional directions is not larger than 0.05×10⁻⁶/° C.

Preferably, the base material has a Shore hardness selected to be in a range of from 60 to 70, both inclusively.

Preferably, recesses are formed on opposite surfaces of the base material.

Preferably, the recesses formed on the opposite surfaces of the base material are the same in shape.

Preferably, the recesses formed on the opposite surfaces of the base material are symmetric to each other with respect to a center plane of the base material.

Preferably, the base material is made of carbon; and the ceramic film is made of SiC.

Preferably, the carbon base material has a coefficient of thermal expansion selected to be in a range of from 4.8×10⁻⁶ to 5.3×10⁻⁶/° C.

### BRIEF DESCRIPTION OF THE PREFERRED EMBODIMENTS

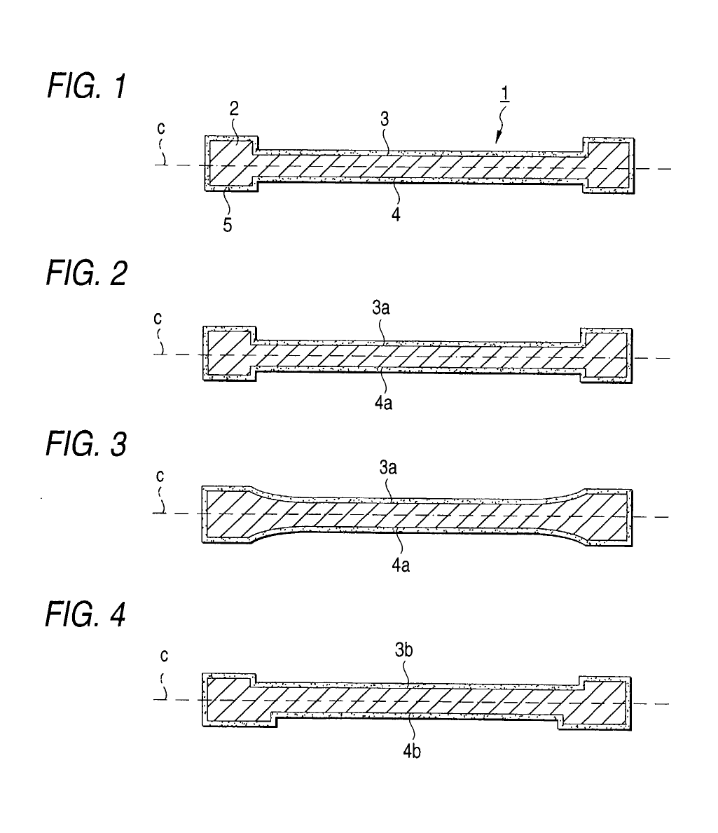

FIG. 1 is a sectional view of a wafer processing member according to an embodiment of the invention;

FIG. 2 is a sectional view of a wafer processing member according to another embodiment of the invention;

FIG. 3 is a sectional view of a wafer processing member according to a further embodiment of the invention;

FIG. 4 is a sectional view of a wafer processing member according to a still further embodiment of the invention;

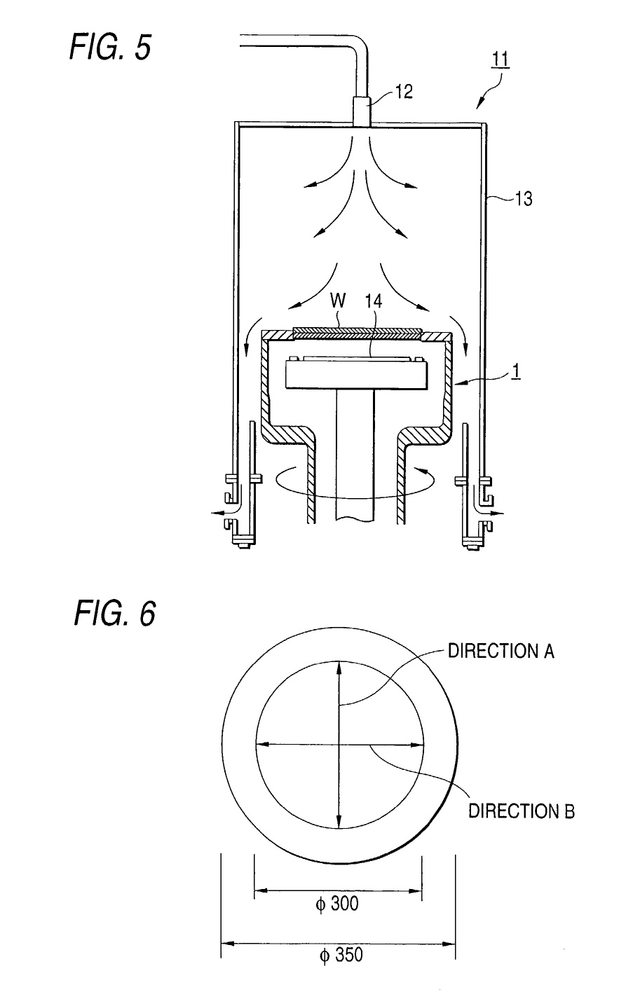

FIG. 5 is a conceptual view showing a state of use of the wafer processing member according to the invention;

FIG. 6 is an explanatory view showing a state in which the wafer processing member according to the invention is used in Examples; and

FIG. 7 is a sectional view of a conventional wafer processing member.

### DETAILED DESCRIPTION OF THE PREFERRED EMBODIMENTS

A first embodiment of a wafer processing member according to the invention will be described with reference to the accompanying drawings.

FIG. 1 is a sectional view of a wafer processing member according to the invention.

As shown in FIG. 1, the wafer processing member 1 has a base material 2, a recess 3 formed on one surface of the base material 2, a recess 4 formed on the other surface of the base material 2, and a ceramic film 5 with which the base material 2 is coated.

The base material 2 is constituted by a base material which is isotropic in all in-plane directions. The thickness of the base material 2 is not larger than 3 mm. Difference in the coefficient of thermal expansion between the base material and the ceramic film is uniform to be in a range of from 0.6×10⁻⁶ to 1.2×10⁻⁶/° C. Variation in the coefficient of thermal expansion of the base material in all in-plane directions is not larger than 0.05×10⁻⁶/° C.

The base material 2 is isotropic in the coefficient of thermal expansion in all in-plane directions. The coefficient of thermal expansion of the base material 2 varies in a thicknesswise (depthwise) direction but the thickness of the base material 2 is not larger than 3 mm. Hence, even in the case where the coefficient of thermal expansion of the base material 2 is not uniform in the thicknesswise (depthwise) direction, the dimension of the resulting wafer processing member 1 varies little in the thicknesswise (depthwise) direction so that high dimensional accuracy is obtained in three-dimensional directions.

When the difference in coefficient of thermal expansion between the base material 2 and the ceramic film 5 is selected to be in a range of from 0.6×10⁻⁶ to 1.2×10⁻⁶/° C., compressive residual stress can be always generated in the ceramic film to thereby prevent the base material from being deformed or to thereby prevent the ceramic film from cracking.

If the difference in coefficient of thermal expansion between the base material 2 and the ceramic film 5 is smaller than 0.6×10⁻⁶/° C., the ceramic film 5 may crack because partial tensile residual stress is applied on the ceramic film 5 due to the shape of the base material 2. If the difference in coefficient of thermal expansion between the base material 2 and the ceramic film 5 is larger than 1.2×10⁻⁶/° C., the base material 2 may be deformed or the ceramic film 5 may crack due to excessive compressive residual stress generated in the ceramic film 5 because the difference in coefficient of thermal expansion between the base material 2 and the ceramic film 5 is too large.

As shown in FIG. 1, the recess 3 is shaped circularly and has a depth, for example, of 1 mm. The recess 4 has the same shape as that of the recess 3 and has a depth, for example, of 0.5 mm. That is, the recesses 3 and 4 are not plane-symmetric to each other with respect to a center plane c. The reason why the recess 4 is provided is to make force applied on the outer circumferential portion of the base material 2 uniform to thereby prevent the wafer processing member 1 (base material 2) from being deformed. The reason is also to prevent the wafer processing member 1 (base material 2) from being deformed due to variation of the ceramic film even in the case where the ceramic film varies with the passage of time (the thickness of the ceramic film after use is eroded by about 5 μm to about 10 μm).

The process of coating the base material 2 with the ceramic film 5 is generally carried out at a high temperature of 1,000° C. to 2,000° C. The base material 2 expands in accordance with the coefficient of thermal expansion compared with its shape at ordinary temperature. In this state, the base material 2 is coated with the ceramic film 5. When the temperature is returned to the ordinary temperature after the base material 2 is coated with the ceramic film 5, the base material 2 tries to contract. The amount of change of the base material 2 at the contracting time is, however, smaller than that at the expanding time because the base material 2 is coated with the ceramic film 5. It is preferable that the thickness of the ceramic film 5 is as uniform as possible. If the thickness of the ceramic film 5 is uneven in a plane, compressive residual stress generated in the ceramic film 5 may become so uneven that the wafer processing member 1 is deformed into a boat shape.

Incidentally, as shown in FIGS. 2 and 3, recesses 3a and 4a may be in a shape relation so that the recesses 3a and 4a are provided to be plane-symmetric to each other with respect to the center plane c. Alternatively, as shown in FIG. 4, recesses 3b and 4b may be provided so as to be different in shape from each other in consideration of conditions of use and design, or the like.

When the wafer processing member according to the invention is used in an epitaxial growth step, temperature control is carried out variously. The wafer processing member 1 is, however, configured so that the difference in coefficient of thermal expansion between the base material 2 and the ceramic film 5 in all in-plane directions is uniform to be in a range of from 0.6×10⁻⁶ to 1.2×10⁻⁶/° C. and so that variation in coefficient of thermal expansion of the base material in all in-plane directions is not larger than 0.05×10⁻⁶/° C. Hence, there is no deformation difference in all in-plane directions. Moreover, the thickness of the base material 2 is not larger than 3 mm. Hence, even in the case where the coefficient of thermal expansion of the base material 2 is not uniform in a thicknesswise (depthwise) direction, the difference in dimensional change in three-dimensional directions is small. Accordingly, the wafer processing member 1 (base material 2) is not deformed. Even in the case where the ceramic film varies with the passage of time, the wafer processing member 1 (base material 2) is not deformed due to the variation of the ceramic film.

A second embodiment of the wafer processing member according to the invention will be described below.

In the first embodiment, the thickness of the base material 2 is not larger than 3 mm, the difference in coefficient of thermal expansion between the base material 2 and the ceramic film 5 is uniform to be in a range of from 0.6×10⁻⁶ to 1.2×10⁻⁶/° C., and variation in coefficient of thermal expansion of the base material 2 in all in-plane directions is not larger than 0.05×10⁻⁶/° C. On the other hand, in the second embodiment, the wafer processing member is configured so that the thickness of the base material 2 is not limited, the difference in coefficient of thermal expansion between the base material 2 and the ceramic film 5 in three-dimensional directions is uniform to be in a range of from 0.6×10⁻⁶ to 1.2×10⁻⁶/° C., and variation in coefficient of thermal expansion of the base material 2 in three-dimensional directions is not larger than 0.05×10⁻⁶/° C.

The base material according to the second embodiment is formed so that the difference in coefficient of thermal expansion between the base material 2 and the ceramic film 5 in three-dimensional directions, that is, in all in-plane direction and a thicknesswise (depthwise) direction is uniform to be in a range of from 0.6×10⁻⁶ to 1.2×10⁻⁶/° C. and so that variation in coefficient of thermal expansion of the base material 2 in three-dimensional directions is not larger than 0.05×10⁻⁶/° C.

The base material 2 is isotropic in coefficient of thermal expansion in three-dimensional directions. Hence, even in the case where the thickness of the base material 2 is larger than 3 mm, there is no deformation difference in all in-plane directions and a thicknesswise (depthwise) direction. Even in the case where the wafer processing member 1 (base material 2) is used in heating treatment at a high temperature, the wafer processing member 1 (base material 2) is not deformed. Further, even in the case where the ceramic film varies with the passage of time, the wafer processing member (base material) is not deformed due to the variation of the ceramic film.

Further, a third embodiment of the wafer processing member according to the invention will be described.

The wafer processing member according to the third embodiment is configured in the same manner as in the first or second embodiment except that a base material having a Shore hardness of from 60 to 70, both inclusively, is used in the wafer processing member and that, for example, carbon is used as the base material and SiC is used as the ceramic film with which the base material is coated.

When the Shore hardness of the base material 2 is selected to be in a range of from 60 to 70, both inclusively, the base material 2 is not deformed even after a large number of heat cycles so that the number of times by which the base material 2 can be used can be increased. If the Shore hardness is smaller than 60, the base material is so soft that it is deformed at a high temperature. If the Shore hardness is larger than 70, the base material is so hard that it is broken.

The reason why carbon is preferably used as the base material is that carbon is excellent in high-temperature heat resistance and high in purity. The reason why SiC is preferably used as the ceramic film is that the difference in coefficient of thermal expansion between carbon and SiC can be reduced.

According to the third embodiment, there can be obtained a wafer processing member which is strong against deformation even in the case where a heat cycle using an ordinary temperature and a high temperature of 800° C. or higher as in a semiconductor producing process is repeated.

### EXAMPLES

A wafer processing member having a base material made of carbon, and a ceramic film made of SiC was used as a general wafer processing member.

[Test 1]

Carbon base materials (Examples 1 to 4) within the range of the wafer processing member according to the invention (that is, the difference in coefficient of thermal expansion between the base material and the ceramic film was in a range of from 0.6×10⁻⁶ to 1.2×10⁻⁶/° C.) and carbon base materials (Comparative Examples 1 to 4) out of range were prepared as shown in Tables 1 and 2. Each of the carbon base materials was worked to have a diameter of 350 mm. A recess having a diameter of 300 mm was formed in the center portion of the base material. Then, each of the carbon base materials was coated with a 60 μm-thick SiC film. Dimensions in directions A and B as shown in FIG. 6 were measured.

Results of the measurement were shown in Tables 1 and 2.

TABLE 1

| | Thermal Expansion | | | | | |
|---|---|---|---|---|---|---|
| | Coefficient | | | Problem in production and | | |
| | (×10⁻⁶/° C.) | | | use | | |
| | Carbon | | Dif- | Quantity of | | |
| | base | SiC | fer- | deformation | | Processed |
| | material | film | ence | (mm) | Crack | Wafer |
| Example 1 | 4.84 | 4.12 | 0.72 | 0.02 | absent | No problem |
| Example 2 | 5.21 | 4.12 | 1.09 | 0.01 | absent | No problem |
| Com- | 4.43 | 4.12 | 0.31 | 0.03 | present | Contamin- |
| parative | | | | | | ation |
| Example 1 | | | | | | |
| Com- | 5.52 | 4.12 | 1.40 | 0.17 | present | Slip, |
| parative | | | | | | contamina- |
| Example 2 | | | | | | tion |

TABLE 2

| | Thermal Expansion | | | | | |
|---|---|---|---|---|---|---|
| | Coefficient (×10⁻⁶ /° C.) | | | | | |
| | Direction | Direction | | Dimension (mm) | | |
| | A | B | Difference | Dimension A | Dimension B | Difference |
| Example 3 | 4.84 | 4.83 | 0.01 | 300.62 | 300.62 | 0.00 |
| Example 4 | 5.36 | 5.31 | 0.05 | 300.98 | 300.97 | 0.01 |
| Comparative | 4.82 | 5.30 | 0.48 | 300.61 | 300.97 | 0.36 |
| Example 3 | | | | | | |
| Comparative | 5.28 | 4.89 | 0.39 | 300.97 | 300.64 | 0.33 |
| Example 4 | | | | | | |

It was found that the wafer processing member obtained in each of Examples 1 and 2 was deformed little and did not crack. On the other hand, it was found that the wafer processing member obtained in each of Comparative Examples 1 and 2 was deformed or cracked so that a problem of contamination, slipping or the like arose in the processed wafer.

It was found that the dimension difference in each of Examples 3 and 4 was very small. On the other hand, it was found that the dimension difference in each of Comparative Examples 3 and 4 was very large and was about 30 times as large as that in Example 4.

[Test 2]

Wafer processing members the same as those used in Examples in Test 1 were used. The Shore hardness of carbon used as the base material in each of the wafer processing members was changed as shown in Table 3. A heat resistance test was performed by repetition of a heat cycle in which each wafer processing member was put into a furnace at 1,100° C. for 10 minutes and then left for 20 minutes after the wafer processing member was taken out of the furnace. The state of each member after 10 heat cycles was examined.

Results of the examination were shown in Table 3.

TABLE 3

| | Shore | |
|---|---|---|
| | hardness | Result |
| Comparative Example 5 | 50 | Deformed |
| Comparative Example 6 | 57 | Deformed |
| Example 5 | 60 | Not deformed |
| Example 6 | 65 | Not deformed |
| Example 7 | 68 | Not deformed |
| Comparative Example 7 | 71 | Broken |

It was found that the wafer processing member obtained in each of Examples 5 to 7 in which the Shore hardness of the base material carbon was in a range of from 60 to 70, both inclusively, was not deformed. On the other hand, it was found that both the wafer processing member having a Shore hardness of 50 obtained in Comparative Example 5 and the wafer processing member having a Shore hardness of 57 obtained in Comparative Example 6 were deformed. It was also found that the wafer processing member having a Shore hardness of 71 obtained in Comparative Example 7 was broken.

According to the invention, there can be provided a wafer processing member which is not thermally deformed due to thermal expansion even in the case where the wafer processing member is used in heating treatment.

That is, there is provided a wafer processing member having: a base material made of a material isotropic in all in-plane directions; and a ceramic film with which the base material is coated; wherein: the base material has a thickness of not larger than 3 mm; difference in coefficient of thermal expansion between the base material and the ceramic film in all in-plane directions is in a range of from 0.6×10⁻⁶ to 1.2×10⁻⁶/° C.; and variation in coefficient of thermal expansion of the base material in all in-plane directions is not larger than 0.05×10⁻⁶/° C. Hence, because there is no difference in variation in all in-plane directions, the base material is not deformed in all in-plane directions. Moreover, the difference in variation in all in-plane directions is small even in the case where the coefficient of thermal expansion of the base material is not uniform in a thicknesswise (depthwise) direction. Hence, the wafer processing member (base material) is not deformed.

Further, there is provided a wafer processing member having: a base material made of a material isotropic in three-dimensional directions; and a ceramic film with which the base material is coated; wherein: difference in coefficient of thermal expansion between the base material and the ceramic film in three-dimensional directions of the base material is in a range of from 0.6×10⁻⁶ to 1.2×10⁻⁶/° C.; and variation in coefficient of thermal expansion of the base material in three-dimensional directions is not larger than 0.05×10⁻⁶/° C. Hence, even in the case where the thickness of the base material is not smaller than 3 mm, there is no deformation difference in all in-plane and thicknesswise (depthwise) directions. Hence, the wafer processing member is not deformed.

Further, the base material has a Shore hardness selected to be in a range of from 60 to 70, both inclusively. Hence, the base material is not deformed even in the case where a heat cycle using an ordinary temperature and a high temperature of 800° C. or higher as in a semiconductor producing process is repeated.

Further, recesses are formed on opposite surfaces of the base material. Hence, force applied on the outer circumferential portion of the base material is made uniform, so that the base material can be more effectively prevented from being deformed. Moreover, in the case where the ceramic film varies with the passage of time, the wafer processing member is not deformed due to the variation of the ceramic film.

Further, the recesses formed on the opposite surfaces of the base material are the same in shape. Hence, force applied on the outer circumferential portion of the base material is made uniform effectively, so that the wafer processing member can be effectively prevented from being deformed.

Further, the recesses formed on the opposite surfaces of the base material are symmetric to each other with respect to a center plane of the base material. Hence, the wafer processing member can be effectively prevented from being deformed.

What is claimed is:

1. A wafer processing member comprising:
a base material made of a material isotropic in all in-plane directions; and
a ceramic film with which said base material is coated;
wherein said base material has a thickness of not larger than 3 mm, difference in coefficient of thermal expansion between said base material and said ceramic film is in a range of from 0.6×10⁻⁶ to 1.2×10⁻⁶/° C., and variation in coefficient of thermal expansion of said base material in all in-plane directions is not larger than 0.05×10⁻⁶/° C.

2. A wafer processing member according to claim 1, wherein said base material has a Shore hardness selected to be in a range of from 60 to 70, both inclusively.

3. A wafer processing member according to claim 1, wherein recesses are formed on opposite surfaces of said base material.

4. A wafer processing member according to claim 3, wherein said recesses formed on said opposite surfaces of said base material are the same in shape.

5. A wafer processing member according to claim 4, wherein said recesses formed on said opposite surfaces of said base material are symmetric to each other with respect to a center plane of said base material.

6. A wafer processing member according to claim 1, wherein:
said base material is made of carbon; and
said ceramic film is made of SiC.

7. A wafer processing member according to claim 6, wherein said carbon base material has a coefficient of thermal expansion selected to be in a range of from 4.8×10⁻⁶ to 5.3×10⁻⁶/° C.

8. A wafer processing member according to claim 2, wherein recesses are formed on opposite surfaces of said base material.

9. A wafer processing member according to claim 8, wherein said recesses formed on said opposite surfaces of said base material are the same in shape.

10. A wafer processing member according to claim 9, wherein said recesses formed on said opposite surfaces of said base material are symmetric to each other with respect to a center plane of said base material.

11. A wafer processing member according to claim 2, wherein:
said base material is made of carbon; and
said ceramic film is made of SiC.

12. A wafer processing member according to claim 11, wherein said carbon base material has a coefficient of thermal expansion selected to be in a range of from 4.8×10⁻⁶ to 5.3×10⁻⁶/° C.

13. A wafer processing member comprising:
a base material made of a material isotropic in three-dimensional directions; and
a ceramic film with which said base material is coated;
wherein difference in coefficient of thermal expansion between said base material and said ceramic film in three-dimensional directions of said base material is in a range of from 0.6×10⁻⁶ to 1.2×10⁻⁶/° C., and variation in coefficient of thermal expansion of said base material in three-dimensional directions is not larger than 0.05×10⁻⁶/° C.

14. A wafer processing member according to claim 13, wherein said base material has a Shore hardness selected to be in a range of from 60 to 70, both inclusively.

15. A wafer processing member according to claim 13, wherein recesses are formed on opposite surfaces of said base material.

16. A wafer processing member according to claim 15, wherein said recesses formed on said opposite surfaces of said base material are the same in shape.

17. A wafer processing member according to claim 16, wherein said recesses formed on said opposite surfaces of said base material are symmetric to each other with respect to a center plane of said base material.

18. A wafer processing member according to claim 13, wherein:
said base material is made of carbon; and
said ceramic film is made of SiC.

19. A wafer processing member according to claim 18, wherein said carbon base material has a coefficient of thermal expansion selected to be in a range of from 4.8×10⁻⁶ to 5.3×10⁻⁶/° C.

20. A wafer processing member according to claim 14, wherein recesses are formed on opposite surfaces of said base material.

21. A wafer processing member according to claim 20, wherein said recesses formed on said opposite surfaces of said base material are the same in shape.

22. A wafer processing member according to claim 21, wherein said recesses formed on said opposite surfaces of said base material are symmetric to each other with respect to a center plane of said base material.

23. A wafer processing member according to claim 14, wherein:
said base material is made of carbon; and
said ceramic film is made of SiC.

24. A wafer processing member according to claim 23, wherein said carbon base material has a coefficient of thermal expansion selected to be in a range of from 4.8×10⁻⁶ to 5.3×10⁻⁶/° C.
